(19) United States
(12) Patent Application Publication
(10) Pub. No.: US 2025/0298088 A1
(43) Pub. Date: Sep. 25, 2025

(54) UNIVERSAL DATA COLLECTION PLATFORM FOR LOOP GAIN IDENTIFICATION AND TUNING IN POWER CONVERTERS

(71) Applicant: Analog Devices, Inc., Wilmington, MA (US)

(72) Inventors: Cecelia China Chu, Cambridge, MA (US); Wenjie Lu, Arlington, MA (US); Leah Alexis Garber, Carlisle, MA (US); Mark Frederick Hartman, Santa Clara, CA (US)

(21) Appl. No.: 19/081,890

(22) Filed: Mar. 17, 2025

Related U.S. Application Data
(60) Provisional application No. 63/569,652, filed on Mar. 25, 2024.

(51) Int. Cl. G01R 31/40; G06F 3/04847; G06T 11/20

(52) U.S. Cl. CPC G01R 31/40; G06F 3/04847; G06T 11/206

(57) ABSTRACT

Systems and methods are provided for verifying operation of one or more power converters. The systems and methods obtain one or more outputs of a power supply and generate a set of metrics based on the one or more outputs of the power supply. The systems and methods store a first set of metadata corresponding to the power supply, the first set of metadata associating a current setting for a plurality of tunable parameters and the set of metrics, and generate, for display, a graphical user interface (GUI) comprising the first set of metadata corresponding to the power supply.

### CLAIM OF PRIORITY

This application claims priority to U.S. Provisional Patent Application No. 63/569,652, filed on Mar. 25, 2024, which is hereby incorporated by reference herein in its entirety.

### FIELD OF THE DISCLOSURE

This document pertains generally, but not by way of limitation, to power converter systems, such as power supplies.

### BACKGROUND

Power converters are essential components in electronic systems. These devices can transform AC to DC, DC to AC, or even modify the voltage and current levels within the same type of electrical power. Setting the parameters of power converters is a critical process to ensure the power converter operates efficiently, safely, and in harmony with the connected load. Collecting measurements based on outputs of the power supply is a key step in verifying proper operation of the power converters.

### OVERVIEW

This disclosure describes, among other things, techniques for verifying operation of power converters.

In some aspects, the techniques described herein relate to a power converter system including: control circuitry (control and measurement circuitry), coupled to a power supply (that includes power supply circuitry) including a plurality of tunable parameters, configured to perform operations including: obtaining one or more outputs of the power supply; generating a set of metrics based on the one or more outputs of the power supply; storing a first set of metadata corresponding to the power supply, the first set of metadata associating a current setting for the plurality of tunable parameters and the set of metrics; and generating, for display, a graphical user interface (GUI) including the first set of metadata corresponding to the power supply.

In some aspects, the techniques described herein relate to a power converter system, wherein the one or more outputs include a Bode plot and a transient response of the power supply.

In some aspects, the techniques described herein relate to a power converter system, wherein the operations include: presenting, in a first portion of the GUI, a first visual representation of the Bode plot; and presenting, simultaneously with the first portion, in a second portion of the GUI, a second visual representation of the transient response.

In some aspects, the techniques described herein relate to a power converter system, wherein the plurality of metrics includes at least one of a minimum voltage excursion, a phase margin, an amount of overshoot in voltage, or an amount of undershoot in voltage.

In some aspects, the techniques described herein relate to a power converter system, the operations including: changing the current setting for the plurality of tunable parameters to a second setting; communicating the second setting to the power supply; and obtaining a second set of outputs of the power supply operating under the second setting for the plurality of tunable parameters.

In some aspects, the techniques described herein relate to a power converter system, the operations including: generating a second set of metrics based on the second set of outputs of the power supply; storing a second set of metadata corresponding to the power supply, the second set of metadata associating the second setting for the plurality of tunable parameters and the second set of metrics; and updating the GUI to present the second set of metadata corresponding to the power supply.

In some aspects, the techniques described herein relate to a power converter system, the operations including: generating training data including the first set of metadata and the second set of metadata.

In some aspects, the techniques described herein relate to a power converter system, the operations including: receiving input including a number of samples to collect as part of a training data set including a plurality of sets of metadata.

In some aspects, the techniques described herein relate to a power converter system, the operations including: automatically generating multiple sets of settings for the plurality of tunable parameters; and automatically causing the power supply to generate respective outputs corresponding to operation of the power supply according to the plurality of tunable parameters associated with each of the multiple sets of settings.

In some aspects, the techniques described herein relate to a power converter system, the operations including: storing, as a first portion of the plurality of sets of metadata, a first output of the power supply in association with a first portion of the multiple sets of settings; and storing, as a second portion of the plurality of sets of metadata, a second output of the power supply in association with a second portion of the multiple sets of settings.

In some aspects, the techniques described herein relate to a power converter system, the operations including: training a machine learning model to generate predictions based on the training data set.

In some aspects, the techniques described herein relate to a power converter system, the operations including: processing the training data by the machine learning model to predict settings for the plurality of tunable parameters of the power supply; computing a deviation between the predicted settings and ground truth information associated with the training data; and updating one or more parameters of the machine learning model based on the computed deviation.

In some aspects, the techniques described herein relate to a power converter system, the operations including: receiving input that specifies a name to associate with the training data set.

In some aspects, the techniques described herein relate to a power converter system, wherein the control and measurement circuitry is part of a first physical component, and wherein the power supply is part of a second physical component.

In some aspects, the techniques described herein relate to a power converter system, the control circuitry configured to simultaneously obtain one or more outputs for computing multiple metrics for the power supply.

In some aspects, the techniques described herein relate to a power converter system, wherein the first physical component is configured to interface with multiple types of power supplies.

In some aspects, the techniques described herein relate to a method including: obtaining, by control and measurement circuitry coupled to a power supply, one or more outputs of the power supply; generating a set of metrics based on the one or more outputs of the power supply; storing a first set of metadata corresponding to the power supply, the first set of metadata associating a current setting for a plurality of tunable parameters and the set of metrics; and generating, for display, a graphical user interface (GUI) including the first set of metadata corresponding to the power supply.

In some aspects, the techniques described herein relate to a method, wherein the one or more outputs include a Bode plot and a transient response of the power supply.

In some aspects, the techniques described herein relate to a method, further including: presenting, in a first portion of the GUI, a first visual representation of the Bode plot; and presenting, simultaneously with the first portion, in a second portion of the GUI, a second visual representation of the transient response.

In some aspects, the techniques described herein relate to a non-transitory computer-readable medium including computer-readable instructions that, when executed by one or more processors, configure the one or more processors to perform operations including: obtaining, by control circuitry coupled to a power supply, one or more outputs of the power supply; generating a set of metrics based on the one or more outputs of the power supply; storing a first set of metadata corresponding to the power supply, the first set of metadata associating a current setting for a plurality of tunable parameters and the set of metrics; and generating, for display, a graphical user interface (GUI) including the first set of metadata corresponding to the power supply.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various examples discussed in the present document.

FIG. 1 is a block diagram of an example of a power converter system, in accordance with various examples.

FIGS. 2-3 are block diagrams of examples GUIs for verifying operation of the power converter system, in accordance with various examples.

FIG. 4 is a flow diagram depicting an example process for verifying operation of a power converter system, in accordance with various examples.

FIG. 5 is a block diagram illustrating an example of a machine upon which one or more examples may be implemented.

### DETAILED DESCRIPTION

Power converters are essential components in electronic systems, enabling the conversion of electrical power from one form to another and/or generation of power to meet specific requirements of the load they are powering. These devices can transform AC to DC, DC to AC, or even modify the voltage and current levels within the same type of electrical power. Setting the parameters of power converters is a critical process that involves configuring various operational aspects such as output voltage, current limits, switching frequency, and controller parameters, among others. Proper parameter setting ensures the power converter operates efficiently, safely, and in harmony with the connected load, thereby optimizing performance and extending the lifespan of both the converter and the load.

In each power supply systems, there are requirements for both output voltage transients (e.g., minimum voltage excursion), and for the closed-loop AC responses (e.g., sufficient phase margin). Modern power supply ICs often have power supply controllers with loop compensation networks that can be tuned to optimize the performance of the power supplies. However, there are many challenges in conventional loop tuning. Specifically, there can be many tunable parameters and tuning these parameters is conventionally performed in a manual process, which is tedious and time-consuming and often leads to non-optimal results.

Achieving optimal compensation in power converters often involves navigating trade-offs between stability, performance, and efficiency. For instance, increasing the bandwidth of the control loop can improve transient response but may also introduce stability issues or increase susceptibility to noise. Similarly, designing for maximum efficiency might compromise performance under certain operating conditions. Identifying the optimal balance requires a deep understanding of the system's behavior and the ability to evaluate the impact of different compensation strategies on overall system performance.

External factors such as temperature, humidity, and electromagnetic interference (EMI) can also pose challenges to setting optimal compensation (tuning) parameters. These conditions can affect both the power converter's components and its control systems, leading to deviations from expected performance. Designing compensation strategies that are resilient to such environmental and operational variations is crucial for ensuring reliable performance in real-world applications, yet this is tedious and time consuming. Compensation parameters that are optimal for one set of conditions may not be suitable for others. Finding the right set of compensation parameters is a daunting task that consumes a great deal of resources and time. In addition, many converters employ performance enhancements or hybrid loops that are combinations of classical control loops which have no de-facto small signal model to design performance and stability with. In these cases tuning the loop is often done empirically without a good understanding of the stability margin.

When evaluating the performance and reliability of power supplies, engineers and technicians often face the challenge of having to use a variety of tools to obtain different measurements (e.g., metrics). This multiplicity of tools can introduce several complications that impact the efficiency, accuracy, and overall effectiveness of the testing and monitoring process. One significant challenge is the complexity of integrating data from different sources. Each tool or instrument used to measure aspects such as voltage ripple, efficiency, thermal performance, or electromagnetic compatibility may have its own data formats, interfaces, and communication protocols. This diversity necessitates additional steps to aggregate, synchronize, and analyze the data, increasing the risk of errors and misinterpretations. Engineers must spend valuable time and resources developing or employing software solutions capable of consolidating this data into a coherent format that is suitable for comprehensive analysis.

Moreover, the need to use different tools often leads to increased setup times and complexity. For each measurement or metric, the power supply must be correctly interfaced with the respective tool, configured according to the specific test requirements, and calibrated to ensure accurate readings. This not only slows down the evaluation process but also introduces more opportunities for human error in the setup and measurement phases. The physical space required to accommodate multiple pieces of testing equipment can also be a concern, especially in laboratories or facilities where space is at a premium. Additionally, the expertise required to operate various specialized tools effectively can be a significant challenge. Each type of measurement may require specific knowledge and experience to obtain accurate and meaningful results. This necessitates a higher level of training and proficiency among the personnel involved, which can be a substantial investment for organizations in terms of both time and financial resources.

According to the disclosed examples, novel and resource-efficient approaches to verify operation of power converter systems (e.g., power supplies) are provided. The disclosed approach provides a more integrated measurement solution that can streamline the testing process and reduce the potential for errors in collecting measurements for a power converter system. Specifically, the disclosed techniques use a single component to obtain one or more outputs of a power supply and generate a set of metrics based on the one or more outputs of the power supply. The disclosed techniques store a first set of metadata corresponding to the power supply, the first set of metadata associating a current setting for a plurality of tunable parameters and the set of metrics and generate, for display, a graphical user interface (GUI) that includes the first set of metadata corresponding to the power supply. The set of metrics that are presented can visually depict a transient response, Bode plot, and various other information associated with outputs and operation of the power supply.

In this way, the disclosed techniques reduce the amount of manual user involvement and time-consuming process and use of multiple types of tools to verify operation of a power supply, which improves the overall efficiencies of designing and operating a power converter system. In addition, the disclosed techniques enable the automated collection of very large and varied datasets with minimal user input in a quick and efficient manner which can then be used to train one or more machine learning (ML) models.

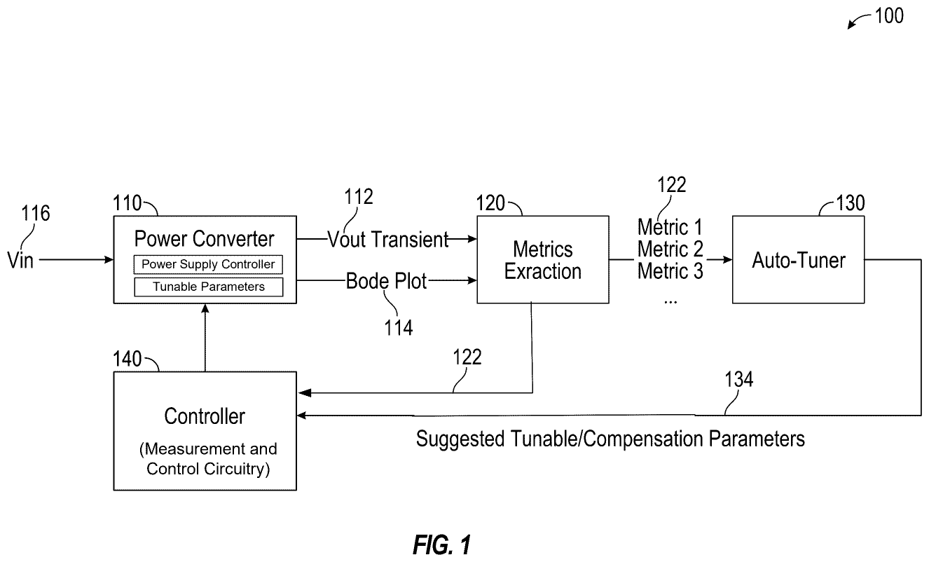

FIG. 1 is a block diagram of an example of a power converter system 100, in accordance with various examples. The power converter system 100 includes a power converter 110 (e.g., a power supply), a metrics extraction component 120, an auto-tuner component 130, and a controller 140 (which can be a component, in whole or in part, of control circuitry). The controller 140 is a measurement and control circuitry and is distinct from the power converter controller that is part of the power converter 110 (e.g., the power supply controller). Namely, there are two different types of controllers used. The power converter controller controls internal operations of the power converter 110, such as the power supply. The measurement controller (or measurement and control circuitry), implemented as controller 140, is used to collect and/or analyze metrics of the power converter 110.

Although the components shown in power converter system 100 are drawn as separate components, they can all be implemented by a single component. For example, the controller 140 can implement the functionality of the metrics extraction component 120 and/or the auto-tuner component 130. In some cases, the controller 140, metrics extraction component 120, and the auto-tuner component 130 can be implemented by a first single physical component, and the power converter 110 can be implemented by a separate second single physical component (e.g., a printed circuit board).

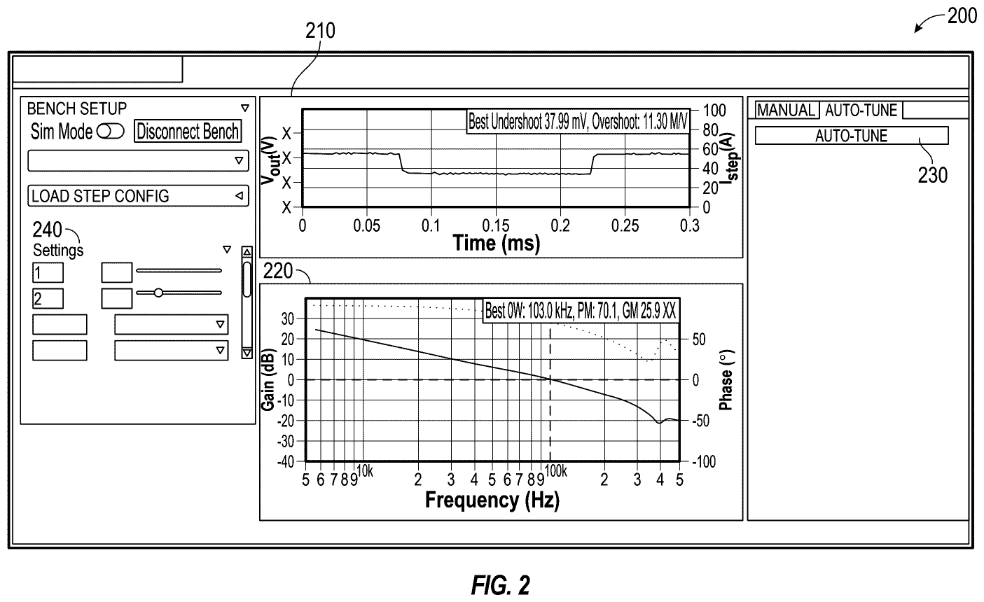

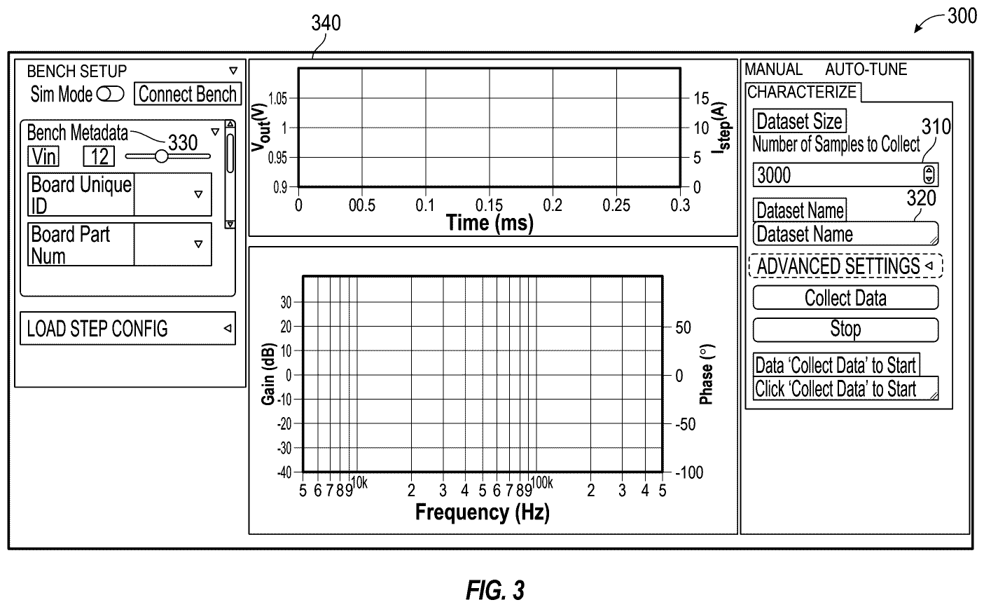

In some examples, the power converter 110 includes a plurality of tunable parameters. In order to configure or adjust the tunable parameters of the power converter 110, an interface can be provided. The interface can be accessed through a GUI coupled to the power converter 110, which can be provided by the controller 140. Example GUIs are discussed below in connection with FIGS. 2 and 3.

In some cases, the interface of the power converter 110 can be accessed by the controller 140. The interface (e.g., an ethernet connection or other serial or parallel physical connection) can be configured to receive a set of instructions that specify the different values for each of the tunable parameters. In some cases, one tunable parameter can be defined by a first type of data, such as a string, and another tunable parameter can be defined by a second type of data, such as a floating point value, an integer value, and/or a Boolean value. The interface can specify the values for each of the tunable parameters. In response to receiving the values for each of the tunable parameters via the interface, the power converter 110 (e.g., the power supply controller) adjusts the tunable parameters and the output (e.g., metrics) of the power converter 110 is generated/collected/analyzed using the adjusted tunable parameters. These parameters can be used to set the switching frequency, voltage and current limits, compensation, and/or control loop gains.

The power converter 110 can be accompanied by proprietary software that allows users and/or the controller 140 to connect to the converter via a communication port (e.g., USB, RS-232, Ethernet, Power Management Bus (PMBus), and so forth) and adjust parameters through a GUI. In some cases, the power converter 110 offers short or long-range wireless connectivity and can be adjusted using mobile applications, providing a convenient way to make changes wirelessly, especially in hard-to-reach installations. In some cases, the power converter 110 (e.g., the power supply controller) can communicate with the controller 140 (e.g., the measurement and control circuitry) via protocols like RS-232, RS-485, and CAN, allowing for the remote adjustment of parameters. In some cases, the power converter 110 can communicate with the controller 140 wirelessly.

The power converter 110 can receive an input voltage 116 and can generate one or more outputs based on that input voltage 116. In some cases, the one or more outputs generated by the power converter 110 can be controlled by modifying one or more of the tunable parameters, such as by providing settings for the one or more tunable parameters. The one or more outputs generated by the power converter 110 can include a voltage output transient response 112 and/or a Bode plot 114. These one or more outputs can be measured and collected simultaneously by a single component that includes the controller 140 and/or the metrics extraction component 120.

In some examples, the metrics extraction component 120 obtains the raw outputs from the power converter 110. The metrics extraction component 120 processes the output (e.g., Bode plot and/or transient response) to generate a set of metrics 122. The set of metrics 122 can represent the raw measurements of the power converter 110 output include any measurable property of the output of the power converter 110. For example, the set of metrics 122 can include voltage metrics (e.g., the average value of the output voltage and/or variation or fluctuation of the output voltage over type measured in peak-to-peak), current metrics (e.g., the average output current or variation in the output current over time), pulse width modulation switching mode (e.g., jitter and/or switching frequency), conversion efficiency, power loss, transient response, stability margins, operating temperature, thermal resistance, overvoltage protection information, overcurrent protection information, short circuit protection information, conducted emissions (e.g., level of electrical noise conduced back into the power source), radiated emissions (e.g., the level of electromagnetic radiation emitted by the converter), an amount of overshoot in voltage, an amount of undershoot in voltage, and/or mean time between failures (e.g., an estimated expected operational lifespan of the converter).

In some cases, the set of metrics 122 can be presented to a user on a GUI. For example, as shown in the GUI 200 of FIG. 2, a first visual representation 210 of a first portion of the set of parameters can be provided simultaneously with a second visual representation 220 of a second portion of the set of parameters. The first visual representation 210 can represent visually a Bode plot of the power converter 110. The second visual representation 220 can represent visually the transient response of the power converter 110. Any other metrics can be simultaneously presented in the GUI 200 together with or separate from the first visual representation 210 and the second visual representation 220. In some cases, input can be received via the GUI 200 that indicates which types of outputs to collect and use to compute and measure metrics. Based on this input, the metrics extraction component 120 generates the visual representation of the outputs corresponding to the indicated types of metrics.

In some examples, the GUI 200 can receive input from a user in a parameters setting portion 240. The input can specify one or more settings of the power converter 110 to adjust. For example, the GUI 200 can receive an adjustment to a first compensation parameter (e.g., tunable parameter) of the power converter 110 from the portion 240. In response, the GUI 200 causes the controller 140 to communicate a change to the tunable parameters of the power converter 110 corresponding to the adjusted first compensation parameter. The metrics extraction component 120 updates the metrics based on new raw outputs of the power converter 110 operating according to the changed tunable parameters. The metrics extraction component 120 updates the first visual representation 210 and the second visual representation 220 to represent the adjusted first compensation parameter. In some examples, the set of metrics 122 can be provided to the auto-tuner component 130. The auto-tuner component 130 can access a set of objectives of an objective function. The set of objectives can include a target value corresponding to the set of metrics 122. For example, the set of objectives can include target output voltage metrics, target stability and/or AC metrics, target current metrics, target conversion efficiency, target power loss, target transient response, target stability margins, target operating temperature, target thermal resistance, target overvoltage protection, target overcurrent protection, target short circuit protection, target conducted emissions (e.g., level of electrical noise conduced back into the power source), target radiated emissions (e.g., the level of electromagnetic radiation emitted by the converter), and/or target mean time between failures (e.g., an estimated expected operational lifespan of the converter).

The auto-tuner component 130 can implement a machine learning model to generate new settings for compensation parameters for the power converter 110 to use. For example, the auto-tuner component 130 can generate a particular set of settings and provides these settings as new set of compensation parameters 134 to the controller 140. The controller 140 can then update the tunable parameters of the power converter 110 through the interface of the power converter 110. In some cases, the auto-tuner component 130 maintains or stores the values of the compensation parameters (e.g., the settings of the tunable parameters) in association with the corresponding outputs of the power converter 110. For example, the auto-tuner component 130 can store a first set of metadata that associates a first set of compensation parameters with a first output of the power converter 110. The auto-tuner component 130 can store a second set of metadata that associates a second set of compensation parameters with a second output of the power converter 110. The auto-tuner component 130 can continue storing metadata sets as different settings for the tuning parameters are received via the portion 240 and used to generate new outputs of the power converter 110. This allows a user to view a history of metadata to visualize how the power converter 110 operated under different settings to select the optimal settings for the power converter 110.

In some examples, the auto-tuner component 130 generates the new set of compensation parameters 134 and provides that new set of compensation parameters 134 to the controller 140. The controller 140 can generate a set of instructions and send those instructions to the power converter 110. The set of instructions can cause the power converter 110 to replace the current set of compensation parameters with the new set of compensation parameters 134 generated by the auto-tuner component 130. The power converter 110 can then operate according to the new set of compensation parameters 134. The output of the power converter 110 can be obtained by the metrics extraction component 120 can used to generate a new set of metrics 122. The auto-tuner component 130 can store an association between a second set of compensation parameters corresponding to the new set of compensation parameters 134 and a second output of the power converter 110 corresponding to the output that is measured based on application of the second set of compensation parameters.

In some examples, an auto-tune option 230 can be presented in the GUI 200. In response to receiving input that selects the auto-tune option 230, the controller 140 can present the GUI 300 shown in FIG. 3. The GUI 300 also includes a region 340 that presents simultaneously multiple types of measurements of the power converter 110, such as a Bode plot and transient response.

The GUI 300 can include various regions for collecting training data for training a machine learning model (e.g., an artificial neural network) implemented at least in part by the auto-tuner component 130. For example, the GUI 300 can present a first option 310 for defining a quantity or number of samples to collect as part of metadata that forms the training data.

In some cases, the GUI 300 receives input that specifies a first quantity or number of samples in the first option 310. In response, the controller 140 generates a random distribution of settings for the tunable parameters by applying various adjustments or modifications to the current tunable parameter settings of the power converter 110. In some cases, the auto-tuner component 130 can process the metrics (discussed above and below) in parallel, such as while, the controller 140 generates the distribution of settings. In some cases, rather than a random distribution of settings, the controller 140 can sequentially adjust settings according to an algorithm which dynamically responds to a current set of metrics to avoid unstable or dangerous configurations. The quantity of settings generated by the controller 140 corresponds to the quantity or number specified in the first option 310. The step size for the adjustments of modifications can be set based on the quantity or number specified in the first option 310. For example, a first quantity or number specified in the first option 310 can result in a first value for the adjustments or modifications to be applied to the current tunable parameter settings to generate the random distribution of settings. A second quantity or number specified in the first option 310 can result in a second value for the adjustments or modifications to be applied to the current tunable parameter settings to generate the random distribution of settings. If the second quantity or number is larger than the first quantity or number, then the second value is smaller than the first value. If the second quantity or number is smaller than the first quantity or number, then the second value is larger than the first value.

The controller 140 can automatically select a first setting from the random distribution of settings. The controller 140 can instruct the power converter 110 to update the tunable parameters based on the first setting. The controller 140 can collect a first set of metrics based on the output of the power converter 110 operating according to the first setting and store a first portion of the training data that includes an association between the first setting and the first set of metrics. The training data can include multiple sets of metadata, training metrics, and/or multiple waveform outputs. The controller 140 can then automatically select a second setting from the random distribution of settings. The controller 140 can instruct the power converter 110 to update the tunable parameters based on the second setting. The controller 140 can collect a second set of metrics based on the output of the power converter 110 operating according to the second setting and store a second portion of the training data that includes an association between the second setting and the second set of metrics. After selecting each of the settings from the random distribution and causing the power converter 110 to operate according to each of the settings, the controller 140 forms training data that includes the multiple portions (each associating a setting with a corresponding set of metrics of the power converter 110). The GUI 300 can receive input that assigns a name to the training data via a name option 320. In some cases, the GUI 300 can also allow the user to specify the type of printed circuit board and/or power converter 110 being tested in a region 330 of the GUI 300.

The controller 140 can train the machine learning model of the auto-tuner component 130 using the training data to generate predictions. The predictions generated by the auto-tuner component 130 can include settings for the tunable parameters of the power converter 110. For example, the machine learning model can process the training data to predict settings for the plurality of tunable parameters of the power supply. The machine learning model computes a deviation between the predicted settings and ground truth information associated with the training data and updates one or more parameters of the machine learning model based on the computed deviation. The machine learning model repeats this process until all portions of the training data are processed and/or until a stopping criterion is reached.

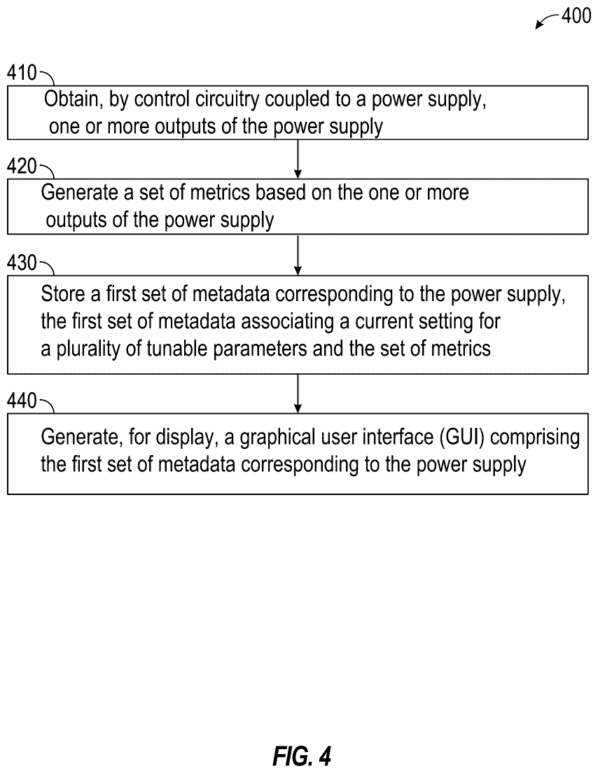

FIG. 4 is a flow diagram depicting example process or method 400 for operating or verifying operation of a power converter system, in accordance with various examples. The operations of the process or method 400 may be performed in parallel or in a different sequence, or may be entirely omitted. In some examples, some or all of the operations of the process or method 400 may be embodied on a computer-readable medium and executed by one or more processors.

At operation 410, control circuitry obtains, by control circuitry coupled to a power supply, one or more outputs of the power supply, as discussed above.

At operation 420, the control circuitry generates a set of metrics based on the one or more outputs of the power supply, as discussed above.

At operation 430, the control circuitry stores a first set of metadata corresponding to the power supply, the first set of metadata associating a current setting for a plurality of tunable parameters and the set of metrics, as discussed above.

At operation 440, the control circuitry generates, for display, a graphical user interface (GUI) comprising the first set of metadata corresponding to the power supply, as discussed above.

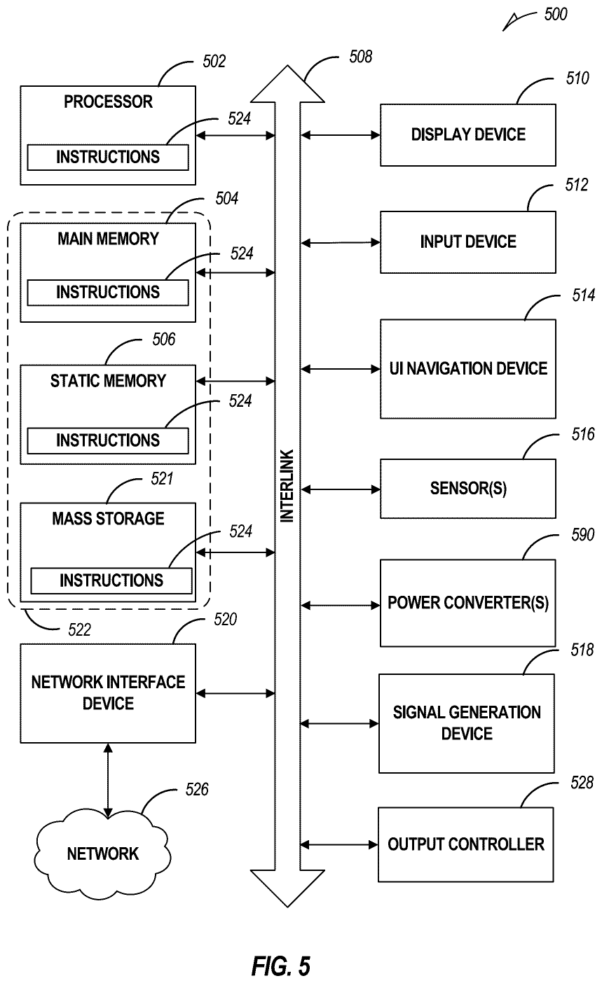

FIG. 5 is a block diagram of an example machine 500 upon which any one or more of the techniques (e.g., methodologies) discussed herein may be performed. In alternative examples, the machine 500 may operate as a standalone device or may be connected (e.g., networked) to other machines. In a networked deployment, the machine 500 may operate in the capacity of a server machine, a client machine, or both in server-client network environments. In an example, the machine 500 may act as a peer machine in a peer-to-peer (P2P) (or other distributed) network environment. The machine 500 may be a personal computer (PC), a tablet PC, a set-top box (STB), a personal digital assistant (PDA), a mobile telephone, a web appliance, an IoT device, an automotive system, an aerospace system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, by moveable placement of invariant-massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 500 may include a hardware processor 502 (e.g., a central processing unit (CPU), a graphics processing unit (GPU), a hardware processor core, or any combination thereof, such as a memory controller, etc.), a main memory 504, and a static memory 506, some or all of which may communicate with each other via an interlink (e.g., bus) 508. The machine 500 may further include a display device 510, an alphanumeric input device 512 (e.g., a keyboard), and a user interface (UI) navigation device 514 (e.g., a mouse). In an example, the display device 510, alphanumeric input device 512, and UI navigation device 514 may be a touchscreen display. The machine 500 may additionally include a storage device 522 (e.g., drive unit); a signal generation device 518 (e.g., a speaker); a network interface device 520; one or more sensors 516, such as a Global Positioning System (GPS) sensor, wing sensor, mechanical device sensor, temperature sensor, bridge sensor, audio sensor, industrial sensor, a compass, an accelerometer, or other sensors; and one or more power converter(s) 590. The power converter(s) 590 may implement some or all of the functionality of the electrolyzer systems, discussed above. The machine 500 may include an output controller 528, such as a serial (e.g., universal serial bus (USB)), parallel, or other wired or wireless (e.g., infrared (IR), near field communication (NFC), etc.) connection to communicate with or control one or more peripheral devices (e.g., a printer, card reader, etc.).

The storage device 522 may include a machine-readable medium on which is stored one or more sets of data structures or instructions 524 (e.g., software) embodying or utilized by any one or more of the techniques or functions described herein. The instructions 524 may also reside, completely or at least partially, within the main memory 504, within the static memory 506, or within the hardware processor 502 during execution thereof by the machine 500. In an example, one or any combination of the hardware processor 502, the main memory 504, the static memory 506, or the storage device 522 may constitute the machine-readable medium.

While the machine-readable medium is illustrated as a single medium, the term “machine-readable medium” may include a single medium or multiple media (e.g., a centralized or distributed database, or associated caches and servers) configured to store the one or more instructions 524.

The term “machine-readable medium” may include any transitory or non-transitory medium that is capable of storing, encoding, or carrying transitory or non-transitory instructions for execution by the machine 500 and that cause the machine 500 to perform any one or more of the techniques of the present disclosure, or that is capable of storing, encoding, or carrying data structures used by or associated with such instructions. Non-limiting machine-readable medium examples may include solid-state memories and optical and magnetic media. In an example, a massed machine-readable medium comprises a machine-readable medium with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 524 (e.g., software, programs, an operating system (OS), etc.) or other data that are stored on the storage device 521 can be accessed by the main memory 504 for use by the hardware processor 502. The main memory 504 (e.g., DRAM) is typically fast, but volatile, and thus a different type of storage from the storage device 521 (e.g., an SSD), which is suitable for long-term storage, including while in an “off” condition. The instructions 524 or data in use by a user or the machine 500 are typically loaded in the main memory 504 for use by the hardware processor 502. When the main memory 504 is full, virtual space from the storage device 521 can be allocated to supplement the main memory 504; however, because the storage device 521 is typically slower than the main memory 504, and write speeds are typically at least twice as slow as read speeds, use of virtual memory can greatly reduce user experience due to storage device latency (in contrast to the main memory 504, e.g., DRAM). Further, use of the storage device 521 for virtual memory can greatly reduce the usable lifespan of the storage device 521.

The instructions 524 may further be transmitted or received over a communications network 526 using a transmission medium via the network interface device 520 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone Service (POTS) networks, and wireless data networks (e.g., Institute of Electrical and Electronics Engineers (IEEE) 802.11 family of standards known as Wi-Fi®, IEEE 802.16 family of standards known as WiMax®, IEEE 802.15.4 family of standards, P2P networks), among others. In an example, the network interface device 520 may include one or more physical jacks (e.g., Ethernet, coaxial, or phone jacks) or one or more antennas to connect to the communications network 526. In an example, the network interface device 520 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible or intangible medium that is capable of storing, encoding, or carrying instructions for execution by the machine 500, and includes digital or analog communications signals or other tangible or intangible media to facilitate communication of such software.

Each of the non-limiting aspects or examples described herein may stand on its own, or may be combined in various permutations or combinations with one or more of the other examples.

The above detailed description includes references to the accompanying drawings, which form a part of the detailed description. The drawings show, by way of illustration, specific examples in which the inventive subject matter may be practiced. These examples are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following aspects, the terms “including” and “comprising” are open-ended; that is, a system, device, article, composition, formulation, or process that includes elements in addition to those listed after such a term in an aspect are still deemed to fall within the scope of that aspect. Moreover, in the following aspects, the terms “first,” “second,” “third,” and so forth are used merely as labels and are not intended to impose numerical requirements on their objects.

Method examples described herein may be machine-or computer-implemented at least in part. Some examples may include a computer-readable medium or machine-readable medium encoded with transitory or non-transitory instructions operable to configure an electronic device to perform methods as described in the above examples. An implementation of such methods may include code, such as microcode, assembly-language code, a higher-level-language code, or the like. Such code may include transitory or non-transitory computer-readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read-only memories (ROMs), and the like.

The above description is intended to be illustrative, and not restrictive. For example, the above-described examples (or one or more aspects thereof) may be used in combination with each other. Other examples may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above detailed description, various features may be grouped together to streamline the disclosure. This should not be interpreted as intending that a disclosed feature not listed in the list of claims is essential to any aspect. Rather, inventive subject matter may lie in less than all features of a particular disclosed example. Thus, the following aspects are hereby incorporated into the detailed description as examples or examples, with each claim standing on its own as a separate example, and it is contemplated that such examples may be combined with each other in various combinations or permutations. The scope of the inventive subject matter should be determined with reference to the appended claims, along with the full scope of equivalents to which such claims are entitled.

1. A power converter system comprising:
control and measurement circuitry, coupled to a power supply comprising a plurality of tunable parameters, configured to perform operations comprising:
obtaining one or more outputs of the power supply;
generating a set of metrics based on the one or more outputs of the power supply;
storing a first set of metadata corresponding to the power supply, the first set of metadata associating a current setting for the plurality of tunable parameters and the set of metrics; and
generating, for display, a graphical user interface (GUI) comprising the first set of metadata corresponding to the power supply.

2. The power converter system of claim 1, wherein the one or more outputs comprise a Bode plot and a transient response of the power supply.

3. The power converter system of claim 2, wherein the operations comprise:
presenting, in a first portion of the GUI, a first visual representation of the Bode plot; and
presenting, simultaneously with the first portion, in a second portion of the GUI, a second visual representation of the transient response.

4. The power converter system of claim 1, wherein the set of metrics comprises at least one of voltage excursion, a phase margin, setting time, ringback, bandwidth, gain margin, or jitter.

5. The power converter system of claim 1, the operations comprising:
changing the current setting for the plurality of tunable parameters to a second setting;
communicating the second setting to the power supply; and
obtaining a second set of outputs of the power supply operating under the second setting for the plurality of tunable parameters.

6. The power converter system of claim 5, the operations comprising:
generating a second set of metrics based on the second set of outputs of the power supply;
storing a second set of metadata corresponding to the power supply, the second set of metadata associating the second setting for the plurality of tunable parameters and the second set of metrics; and
updating the GUI to present the second set of metadata corresponding to the power supply.

7. The power converter system of claim 6, the operations comprising:
generating training data comprising the first set of metadata, the second set of metadata, one or more training metrics, and one or more waveform outputs.

8. The power converter system of claim 6, the operations comprising:
receiving input comprising a number of samples to collect as part of a training data set comprising a plurality of sets of metadata.

9. The power converter system of claim 8, the operations comprising:
automatically generating multiple sets of settings for the plurality of tunable parameters; and
automatically causing the power supply to generate respective outputs corresponding to operation of the power supply according to the plurality of tunable parameters associated with each of the multiple sets of settings.

10. The power converter system of claim 9, the operations comprising:
storing, as a first portion of the plurality of sets of metadata, a first output of the power supply in association with a first portion of the multiple sets of settings; and
storing, as a second portion of the plurality of sets of metadata, a second output of the power supply in association with a second portion of the multiple sets of settings.

11. The power converter system of claim 9, the operations comprising:
training a machine learning model to generate predictions based on the training data set.

12. The power converter system of claim 11, the operations comprising:
processing training data by the machine learning model to predict settings for the plurality of tunable parameters of the power supply;
computing a deviation between the predicted settings and ground truth information associated with the training data; and
updating one or more parameters of the machine learning model based on the computed deviation.

13. The power converter system of claim 9, the operations comprising:
receiving input that specifies a name to associate with the training data set.

14. The power converter system of claim 1, wherein the control and measurement circuitry is part of a first physical component, and wherein the power supply is part of a second physical component.

15. The power converter system of claim 14, the control and measurement circuitry configured to simultaneously obtain the one or more outputs for computing multiple metrics for the power supply.

16. The power converter system of claim 15, wherein the first physical component is configured to interface with multiple types of power supplies.

17. A method comprising:
obtaining, by control and measurement circuitry coupled to a power supply, one or more outputs of the power supply;
generating a set of metrics based on the one or more outputs of the power supply;
storing a first set of metadata corresponding to the power supply, the first set of metadata associating a current setting for a plurality of tunable parameters and the set of metrics; and
generating, for display, a graphical user interface (GUI) comprising the first set of metadata corresponding to the power supply.

18. The method of claim 17, wherein the one or more outputs comprise a Bode plot and a transient response of the power supply.

19. The method of claim 18, further comprising:
presenting, in a first portion of the GUI, a first visual representation of the Bode plot; and
presenting, simultaneously with the first portion, in a second portion of the GUI, a second visual representation of the transient response.

20. A non-transitory computer-readable medium comprising computer-readable instructions that, when executed by one or more processors, configure the one or more processors to perform operations comprising:
obtaining, by control and measurement circuitry coupled to a power supply, one or more outputs of the power supply;
generating a set of metrics based on the one or more outputs of the power supply;
storing a first set of metadata corresponding to the power supply, the first set of metadata associating a current setting for a plurality of tunable parameters and the set of metrics; and
generating, for display, a graphical user interface (GUI) comprising the first set of metadata corresponding to the power supply.
